(19) United States
(12) Patent Application Publication
(10) Pub. No.: US 2026/0033220 A1
(43) Pub. Date: Jan. 29, 2026

(54) DISPLAY DEVICE INCLUDING A TOUCH INSULATION LAYER AND A REFLECTION ADJUSTMENT LAYER, ELECTRONIC DEVICE, AND METHOD FOR MANUFACTURING A DISPLAY DEVICE

(71) Applicant: SAMSUNG DISPLAY CO., LTD., YONGIN-SI (KR)

(72) Inventors: OHJEONG KWON, Yongin-si (KR); JONGHO SON, Yongin-si (KR); SEUNGYEON JEONG, Yongin-si (KR); TAEHO KIM, Yongin-si (KR); DUCKJONG SUH, Yongin-si (KR)

(21) Appl. No.: 19/189,848

(22) Filed: Apr. 25, 2025

(30) Foreign Application Priority Data
Jul. 24, 2024 (KR) 10-2024-0097959

(51) Int. Cl. H10K 59/80; C09B 1/00; C09B 19/00; C09B 57/00; C09B 57/12; C09K 19/12; C09K 19/16; C09K 19/20; C09K 19/34; H10K 59/12; H10K 59/122; H10K 59/40

(52) U.S. Cl. CPC H10K 59/878; C09B 1/007; C09B 19/00; C09B 57/007; C09B 57/12; C09K 19/12; C09K 19/16; C09K 19/20; C09K 19/348; C09K 19/3491; H10K 59/1201; H10K 59/122; H10K 59/40; C09K 2019/122; C09K 2019/161; C09K 2019/2035; C09K 2019/2078

(57) ABSTRACT

A display device may include a display panel, a touch sensing layer, and a reflection adjustment layer. The touch sensing layer may include a touch insulation layer. The touch insulation layer may include a colorant and may cover a first light-emitting region. The reflection adjustment layer may be disposed on the touch sensing layer. The reflection adjustment layer may include a first adjustment portion which is non-polarized and a second adjustment portion which is polarized. The first adjustment portion may cover the first light-emitting region, and the second adjustment portion may cover a second light-emitting region. The display panel may be configured to emit light of a first wavelength band through the first light-emitting region, and the touch insulation layer may be configured to selectively transmit light of the first wavelength band.

### CROSS-REFERENCE TO RELATED APPLICATIONS

This application claims priority under 35 U.S.C § 119 to Korean Patent Application No. 10-2024-0097959, filed on Jul. 24, 2024, in the Korean Intellectual Property Office, the contents of which are herein incorporated by reference in its entirety.

### BACKGROUND

### 1. Technical Field

The present disclosure relates to a display device including a touch insulation layer and a reflection adjustment layer and a manufacturing method thereof, and more specifically, to a display device with improved light efficiency and visibility, as well as a manufacturing method thereof.

### 2. Discussion of Related Art

Organic light-emitting display (OLED) devices have a self-emissive characteristic in which each pixel may produce light. Unlike liquid crystal display devices, OLED devices do not require a separate light source, thus allowing for reduced thickness and weight. Additionally, OLED devices may exhibit low power consumption, high brightness, and high response speed.

Methods and structures for reducing external light reflection and increasing transmittance may further improve the light efficiency and visibility of display devices.

### SUMMARY

An object of the present disclosure is to provide a display device with improved light efficiency and visibility.

Another object of the present disclosure is to provide a method of manufacturing a display device with improved light efficiency and visibility.

A display device according to an embodiment of the present disclosure may include a display panel, a touch sensing layer, and a reflection adjustment layer. The display panel may have a plurality of light-emitting regions configured for displaying images defined therein. The touch sensing layer may be disposed on the display panel. The reflection adjustment layer may be disposed on the touch sensing layer.

The touch sensing layer may include a touch insulation layer. On a plane, the touch insulation layer may cover a first light-emitting region of the plurality of light-emitting regions and may expose a second light-emitting region of the plurality of light-emitting regions. The touch insulation layer may include a colorant.

The reflection adjustment layer may include a first adjustment portion covering the first light-emitting region and a second adjustment portion covering the second light-emitting region. The first adjustment portion may be non-polarized, and the second adjustment portion may be polarized. According to an embodiment of the present disclosure, the first and second adjustment portions may have an integrated shape.

In an embodiment of the present disclosure, the display panel may be configured to emit light of a first wavelength band through the first light-emitting region. In an embodiment, the touch sensing layer may include a first electrode, a second electrode, and the touch insulation layer is disposed between the first electrode and the second electrode. In an embodiment, the touch insulation layer may be configured to selectively transmit the light of the first wavelength band. According to an embodiment of the present disclosure, the display panel may be configured to emit blue light through the first light-emitting region and to absorb light of another color.

According to an embodiment of the present disclosure, the first adjustment portion may include liquid crystals, and the second adjustment portion may include the liquid crystals and a dichroic dye. According to an embodiment of the present disclosure, the liquid crystals may include lyotropic liquid crystals or host-guest liquid crystals. In an embodiment of the present disclosure, a width of the first adjustment portion may be larger than a width of the first light-emitting region.

A manufacturing method of a display device according to an embodiment of the present disclosure may include preparing a display panel, forming a touch sensing layer, and forming a reflection adjustment layer.

A step of preparing the display panel may include forming a pixel defining layer, a plurality of light-emitting layers, a plurality of pixel electrodes, and an encapsulation layer on a substrate.

A step of forming the touch sensing layer may include forming a touch sensing layer on the display panel, the touch sensing layer including a touch insulation layer, the touch insulation layer overlapping with a first light-emitting layer of the plurality of light-emitting layers and being configured to selectively transmit light with a wavelength band overlapping with that of light emitted from the first light-emitting layer.

The reflection adjustment layer may be formed on the touch sensing layer. A step of forming the reflection adjustment layer may include providing a liquid crystal compound on the touch sensing layer. A step of forming the reflection adjustment layer may include dyeing the liquid crystal compound to form a dyed pattern overlapping with a second light-emitting layer of the plurality of light-emitting layers and surrounding at least a portion of the first light-emitting layer.

In an embodiment of the present disclosure, a step of providing the liquid crystal compound may be performed using a lyotropic liquid crystal or a host-guest liquid crystal. In an embodiment of the present disclosure, a step of providing the liquid crystal compound may include coating the lyotropic liquid crystal that is self-aligned. In an embodiment of the present disclosure, a step of providing the liquid crystal compound may include coating the host-guest liquid crystal and aligning the host-guest liquid crystal.

In an embodiment of the present disclosure, a step of dyeing may include forming a photoresist, forming a dyeing pattern, dyeing the dichroic dye, and removing the photoresist. A step of forming the photoresist may include forming the photoresist on a liquid crystal compound. A step of forming the dyeing pattern may include exposing and developing the photoresist to form the dyeing pattern so that a portion of the liquid crystal compound is exposed. A step of dyeing may include dyeing a dichroic dye on the dyeing pattern to form the dyed pattern.

A display device according to another embodiment of the present disclosure may include a display panel, a touch sensing layer, and a reflection adjustment layer. The touch sensing layer may include a touch insulation layer. On a plane, the touch insulation layer may cover a first light-emitting region of the plurality of light-emitting regions and may expose a second light-emitting region of the plurality of light-emitting regions. The touch insulation layer may include a colorant. The reflection adjustment layer may include a first adjustment portion covering the first light-emitting region and a second adjustment portion covering the second light-emitting region. The first adjustment portion may by non-polarized and the second adjustment portion may be polarized.

In an embodiment, the first and second adjustment portions may have an integrated shape.

In an embodiment of the present disclosure, the display panel may be configured to emit a first wavelength band through the first light-emitting region. In an embodiment, the touch sensing layer may include a first electrode, a second electrode, and the touch insulation layer is disposed between the first electrode and the second electrode. In an embodiment, the touch insulation layer may be configured to selectively transmit light of the first wavelength band.

According to certain embodiments of the present disclosure, the color purity of the light transmitted through the touch insulation layer containing a colorant and the reflection adjustment layer configured to adjust external light reflection may be improved, and external light reflection may be inhibited or prevented, and a display device with improved light efficiency and visibility may be provided, as well as a method of manufacturing the same.

### BRIEF DESCRIPTION OF THE DRAWINGS

These and/or other features will become apparent and more readily appreciated from the following description of various embodiments, taken in conjunction with the accompanying drawings in which:

FIG. 1 is a perspective view of a display device according to an embodiment of the present disclosure;

FIG. 2 is a cross-sectional view schematically illustrating the display device according to an embodiment of the present disclosure;

FIG. 3 is an exemplary diagram illustrating an example of a touch sensing layer TSL;

FIG. 4 is a cross-sectional view illustrating an embodiment of a display device;

FIG. 5 is a graph showing the light transmittance of samples of the touch insulation layer;

FIG. 6 is a flowchart illustrating a method of manufacturing a display device according to an embodiment of the present disclosure;

FIGS. 7A, 7B, 7C, 7D, 7E, and 7F are cross-sectional views sequentially illustrating part of a method of manufacturing a display device according to an embodiment of the present disclosure;

FIG. 7G is a cross-sectional view illustrating an embodiment of a display device;

FIG. 8 is an exemplary block diagram of an electronic device according to an embodiment; and

FIG. 9 illustrates schematic diagrams of electronic devices according to different embodiments.

### DETAILED DESCRIPTION

Reference will now be made in detail to certain embodiments, of which examples are illustrated in the accompanying drawings, where like reference numerals refer to like elements throughout. Embodiments may have a variety of forms and permutations, but the present disclosure shall by no means be construed as being limited by described embodiments. Rather, the present disclosure shall be construed to encompass all forms, permutations, equivalents and substitutes covered by the technical ideas and scope of the present disclosure. Accordingly, embodiments are merely described herein, by referring to the figures, to explain features of the present disclosure.

When an element (or region, layer, portion, etc.) is described to be “disposed on,” “placed on,” “arranged on,” “connected to,” or “coupled to” another element, it shall be construed as being disposed on, placed on, arranged on, connected to, or coupled to the other element directly, but also as possibly having another element therebetween. On the other hand, if one element is described to be “directly disposed on,” “directly placed on,” “directly arranged on,” “directly connected to,” or “directly coupled to” another element, it shall be construed that there is no other element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, etc. illustrated in the drawings.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

Moreover, relative terms, such as “below,” “under,” “beneath,” “lower,” “bottom,” “above,” “over,” “upper,” “top,” etc., may be used herein to describe an element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The exemplary term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The exemplary term “below” or “beneath” can therefore encompass an orientation of both above and below.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

In the present specification, “A is directly disposed on B” means that no separate adhesive layer or bonding member is disposed between the configuration of A and the configuration of B. The configuration of B may be formed on the base surface provided by the configuration of A in a successive process after the configuration of A is formed.

In the present specification, embodiments may be differently implemented, and for example, a specified order of a process may be performed differently than a described order. For example, two processes described to be performed sequentially may be performed simultaneously or performed in a reverse order.

In the present specification, “upper,” “top,” and “upper surface” refer to an upward direction (i.e., a third direction) relative to the display device DD, and “lower,” “bottom,” and “lower surface” refer to a downward direction, that is, the opposite of the third direction. In addition, “left,” “right,” “upper,” and “lower” refer to directions when viewing the display device DD from a planar perspective.

Hereinafter, certain embodiments of the present disclosure will be described with reference to the accompanying drawings.

In an embodiment, a display device according to an embodiment of the present disclosure may include a display panel, a touch sensing layer, and a reflection adjustment layer. The display panel may have a plurality of light-emitting regions configured for displaying images defined therein. The touch sensing layer may be disposed on the display panel and may include a touch insulation layer having a colorant forming a dyed pattern. The reflection adjustment layer may be disposed on the touch sensing layer and may include a non-polarized portion corresponding to the colorant and a polarized portion surrounding at least a portion of the non-polarized portion. External light incident into the non-polarized portion may not be polarized, and when this external light reaches the touch insulation layer, a portion of the light may pass through, while another portion of the light may be absorbed. The portion of the light having passed through the touch insulation layer may be reflected inside the display device and re-emitted externally. External light incident into the polarized portion may be linearly polarized, which may reduce the reflectivity of external light incident on the display device and improve the display quality and visibility of the display device.

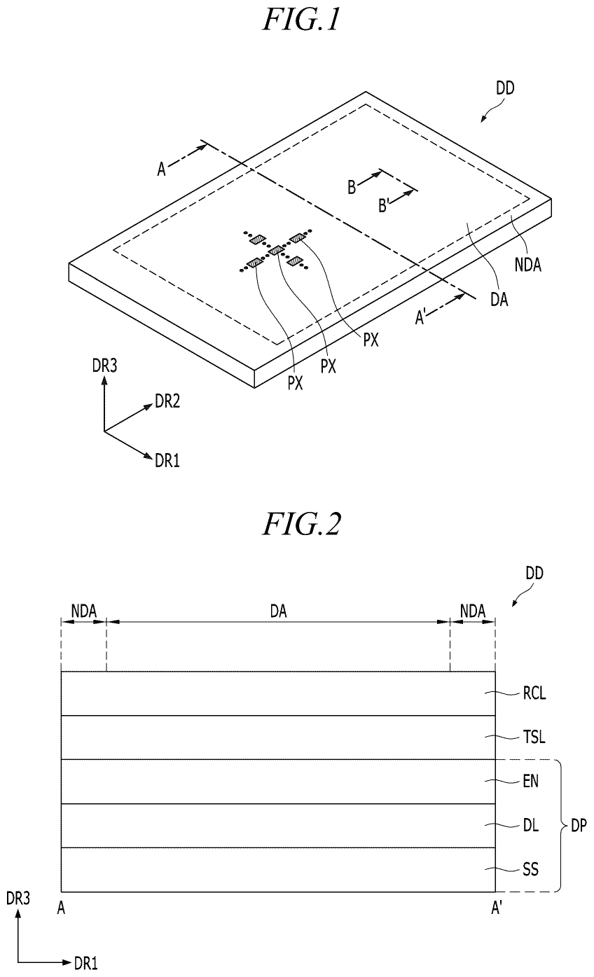

FIG. 1 is a perspective view of a display device according to an embodiment of the present disclosure. Referring to FIG. 1, a display device DD is a device for displaying moving or still images and may be used as a display screen in various products, including portable electronic devices such as mobile phones, smartphones, tablet personal computers (PC), smartwatches, watch phones, portable communication terminals, electronic notebooks, e-books, portable multimedia players (PMP), navigation devices, or Ultra Mobile PCs (UMPC), as well as in products like televisions, laptops, monitors, billboards, or Internet of Things (IoT) devices. The display device DD may be one of an organic light-emitting display device, a liquid crystal display device, a plasma display device, a field emission display device, an electrophoretic display device, an electrowetting display device, a quantum dot light-emitting display device, or a micro-LED display device. Although the following description primarily focuses on an embodiment where the display device DD is an organic light-emitting display device, the present disclosure is not limited thereto.

The display device DD according to an embodiment may include a display area DA and a non-display area NDA located outside the display area DA. In FIG. 1, the display area DA is shown as having a roughly rectangular shape, but the present disclosure is not limited thereto. The display area DA may be provided having various shapes, such as a circular shape, an elliptical shape, or a polygonal shape.

The display area DA includes a portion configured to displays images, and may include a plurality of pixels PX arranged in the display area DA. Each pixel PX may include a light-emitting diode, such as an organic light-emitting diode (OLED). Each pixel PX may be configured to emit light, for example, red, green, blue, or white light.

The display area DA may be configured to provide a predetermined image through the light emitted from the pixels PX. As described above, the term pixel PX in the present specification may be defined as a light-emitting region configured to emit light of a red color, a green color, a blue color, or a white color.

The non-display area NDA is a region in which pixels PX are not arranged and images are not provided. Arranged in the non-display area NDA may be power supply wiring, which is for driving the pixels PX, and terminal parts to which a printed circuit board, which includes a driving circuit, or driver IC is connected.

Hereinafter, an organic light-emitting display device will be described as an example of the display device DD according to an embodiment of the present disclosure. However, the display device DD according to an embodiment of the present disclosure is not limited thereto. The display device DD according to an embodiment may be an inorganic light-emitting display device (or an inorganic EL display device) or a display device such as a quantum dot light-emitting display (QLED). For example, the light-emitting diode provided in the display device DD may include a light-emitting layer that contains an organic or inorganic material. Moreover, quantum dots may be disposed in the optical path of the light emitted from the light-emitting layer.

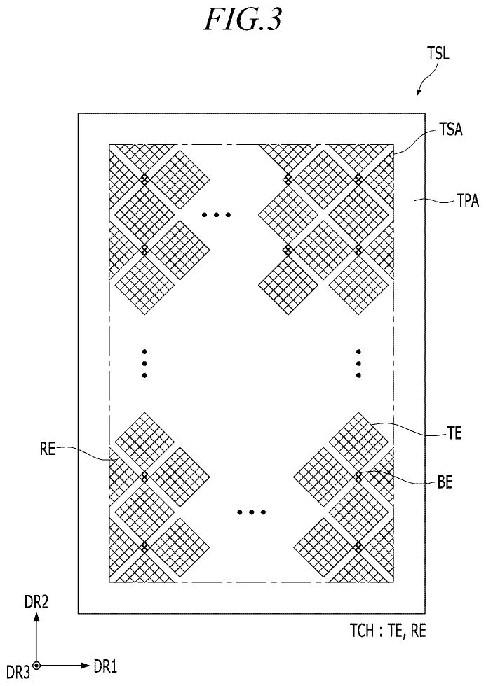

FIG. 2 is a cross-sectional view schematically illustrating a display device according to an embodiment of the present disclosure. The cross-sectional view shown in FIG. 2 is taken along line A-A′ of the display device shown in FIG. 1. Referring to FIG. 2, the display device DD according to an embodiment of the present disclosure may include a substrate SS, a display layer DL, an encapsulation layer EN, a touch sensing layer TSL, and a reflection adjustment layer RCL. The display layer DL may be disposed on the substrate SS. The encapsulation layer EN may be disposed on the display layer DL. The touch sensing layer TSL may be disposed on the encapsulation layer EN. The reflection adjustment layer RCL may be disposed on the touch sensing layer TSL. The substrate SS, the display layer DL, and the encapsulation layer EN may form a display panel DP.

The substrate SS may be a member that provides a base surface on which the display layer DL may be disposed. The substrate SS may include glass or a polymer resin. For example, the polymer resin may include polyethersulfone, polyacrylate, polyetherimide, polyethylene naphthalate, polyethylene terephthalate, polyphenylene sulfide, polyarylate, polyimide, polycarbonate, or cellulose acetate propionate. The substrate SS, which includes a polymer resin, may have flexible, rollable, or bendable characteristics. The substrate SS may have a multilayer structure that includes a layer of polymer resin and an inorganic layer.

The display layer DL may be disposed on the substrate SS. The display layer DL may include organic light-emitting diodes, which are display diodes, a pixel circuit electrically connected to the organic light-emitting diodes, and insulation layers interposed between them. The display layer DL may also include one or more of scan lines, data lines, or power lines connected to the pixel circuit, as well as a scan driver for applying scan signals to the scan lines and fan-out wiring for connecting the data lines to a display driver.

The encapsulation layer EN may be disposed on the display layer DL. At least a portion of the display layer DL may be sealed by the encapsulation layer EN. The encapsulation layer EN may include at least one inorganic encapsulation layer and at least one organic encapsulation layer. The organic encapsulation layer may provide a more planar base surface, thereby reducing defects even when the touch sensing layer TSL, which will be described below, is formed in a continuous process.

The touch sensing layer TSL may be disposed on the display panel DP. For example, the touch sensing layer TSL may be disposed on the encapsulation layer EN of the display panel DP. In an embodiment, the touch sensing layer TSL may be disposed directly on the encapsulation layer EN. Alternatively, the touch sensing layer TSL may be formed separately and then disposed on the encapsulation layer EN. For example, the touch sensing layer TSL may be attached to the encapsulation layer EN via an adhesive layer, such as an optically clear adhesive.

The touch sensing layer TSL may be configured to detect external inputs, such as touches made by a finger or a stylus pen, to enable the display device DD to acquire coordinate information corresponding to the touch location. The touch sensing layer TSL may include touch electrodes and trace lines connected to the touch electrodes. The operation mode of the touch sensing layer TSL is not particularly limited in this disclosure, and for example, the touch sensing layer TSL may be configured to detect external inputs using a mutual capacitance method or a self-capacitance method.

The reflection adjustment layer RCL may be disposed on the touch sensing layer TSL. By reducing the reflectivity of external light incident on the display device DD, the reflection adjustment layer RCL may improve the display quality and visibility of the display device DD. For example, color bleeding may be decreased. Details of the reflection adjustment layer RCL are described herein.

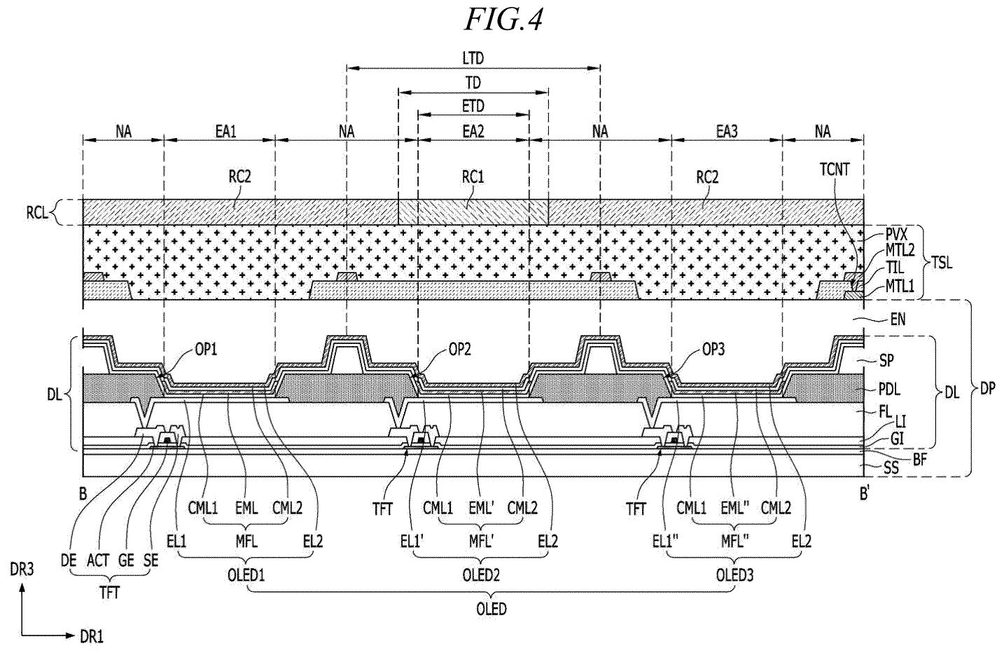

FIG. 3 is an exemplary diagram illustrating an example of the touch sensing layer TSL. Referring to FIG. 3, the touch sensing layer TSL may include a touch sensor area TSA for detecting touches and a touch peripheral area TPA, which may be disposed around at least a portion of the touch sensor area TSA. The touch sensor area TSA may overlap with the display area DA, and the touch peripheral area TPA may overlap with the non-display area NDA.

The touch sensing layer TSL may include a plurality of touch electrodes TCH. The touch electrodes TCH may be disposed in the touch sensor area TSA. The touch electrodes TCH may include a driving electrode TE and a sensing electrode RE. The sensing electrode RE may be electrically connected in a first direction DR1, and the driving electrode TE may be electrically connected in a second direction DR2 that intersects the first direction DR1. In an embodiment of the present disclosure, the driving electrode TE and the sensing electrode RE may each be provided in plurality.

To inhibit or prevent short circuits between the sensing electrodes RE and the driving electrodes TE at their intersection areas, adjacent driving electrodes TE in the second direction DR2 may be electrically connected through a connection electrode BE. Although it is described that, in an embodiment of the present disclosure, the adjacent driving electrodes TE may be connected via the connection electrode BE, the present disclosure is not limited thereto, and the sensing electrodes RE may also be connected through the connection electrode BE.

In such a case, the driving electrodes TE and the sensing electrodes RE may be disposed in the same layer, while the connection electrode BE may be disposed in a different layer from the driving electrodes TE and the sensing electrodes RE. The connection electrode BE may be connected to the driving electrode TE, which may be disposed in another layer, through a touch contact hole TCNT. Additionally, the sensing electrodes RE, which are electrically connected in the first direction DR1, and the driving electrodes TE, which are electrically connected in the second direction DR2, may be electrically insulated from each other.

The touch sensing layer TSL may further include a touch insulation layer, which may be disposed between the touch electrodes TCH and the connection electrode BE. The touch insulation layer may be disposed between the touch electrodes TCH and the connection electrode BE. An example of the touch insulation layer is described herein.

Disposed in the touch peripheral area TPA may be touch lines electrically connected to the touch electrodes TCH and a touch driving circuit connected to the touch electrodes TCH via the touch lines. The touch driving circuit may be disposed on a circuit board that includes one or more circuits for driving the display device DD. The touch driving circuit may be configured to apply driving signals to the touch electrodes TCH of the touch sensing layer TSL and measure the capacitance values of the touch electrodes. The driving signal may be a signal having a plurality of driving pulses. The touch driving circuit may determine the presence or absence of a touch input based on the capacitance values and calculate the touch coordinates at which the touch input was made.

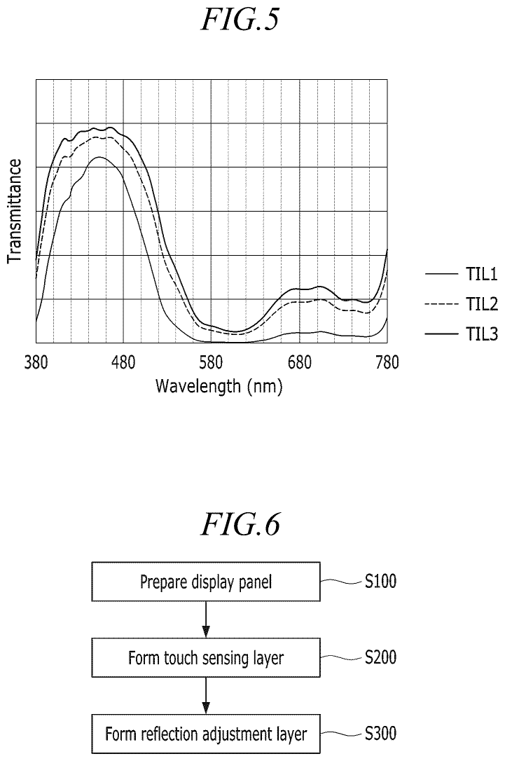

FIG. 4 is a cross-sectional view illustrating an embodiment of the display device. FIG. 4 is a cross-sectional view taken along line B-B′ of FIG. 1. Referring to FIG. 4, the display device DD according to an embodiment of the present disclosure may include a substrate SS, a display layer DL, an encapsulation layer EN, a touch sensing layer TSL, and a reflection adjustment layer RCL. The substrate SS, the display layer DL, and the encapsulation layer EN may form a display panel DP.

The display layer DL may include a buffer layer BF, transistors TFT, a gate insulating layer GI, an interlayer insulating layer LI, a planarization layer FL, organic light-emitting diodes OLED, a pixel defining layer PDL, and spacers SP.

The buffer layer BF may be disposed on the substrate SS. The buffer layer BF may be configured to reduce or block the penetration of external elements, such as foreign substances or moisture, from the lower side of the substrate SS. Additionally, the buffer layer BF may provide a planar surface on the upper surface of the substrate SS.

The buffer layer BF may include silicon oxide (SiO₂) or silicon nitride (SiNx). In an embodiment, a barrier layer for blocking the penetration of external elements may be disposed between the substrate SS and the buffer layer BF. The barrier layer may include an inorganic insulating material.

Transistors TFT may be disposed on the buffer layer BF. Each transistor TFT may include a semiconductor layer ACT, a gate electrode GE, a source electrode SE, and a drain electrode DE. Each transistor TFT may be electrically connected to and configured to drive a first pixel electrode EL1 of a first organic light-emitting diode OLED1, a second pixel electrode EL1′ of a second organic light-emitting diode OLED2, and a third pixel electrode EL1″ of a third organic light-emitting diode OLED3. The first organic light-emitting diode OLED1 may disposed in the first light-emitting region, the second organic light-emitting diode OLED2 may be disposed in the second light-emitting region, and the third organic light-emitting diode OLED 3 may be disposed in the third light-emitting region.

The semiconductor layer ACT may be disposed on the buffer layer BF and may include polysilicon. Alternatively, the semiconductor layer ACT may include amorphous silicon. Alternatively, the semiconductor layer ACT may include an oxide of at least one of indium (In), gallium (Ga), tin (Sn), zirconium (Zr), vanadium (V), hafnium (Hf), cadmium (Cd), germanium (Ge), chromium (Cr), titanium (Ti), or zinc (Zn). The semiconductor layer ACT may include a channel region, a source region, and a drain region. For example, the source and drain regions may be doped with impurities.

The gate electrode GE, source electrode SE, and drain electrode DE may be formed from various conductive materials. The gate electrode GE may include at least one of molybdenum, aluminum, copper, or titanium. For example, the gate electrode GE may be a single layer of molybdenum or a three-layer structure that includes a molybdenum layer, an aluminum layer, and a molybdenum layer. The source electrode SE and drain electrode DE may include a material including at least one of copper, titanium, or aluminum. For example, the source electrode SE and drain electrode DE may have a three-layer structure that includes a titanium layer, an aluminum layer, and a titanium layer. In an embodiment, the source electrode SE or the drain electrode DE may be omitted, and the source or drain region of the semiconductor layer ACT may function as the source electrode or drain electrode.

The gate insulating layer GI may be disposed between the semiconductor layer ACT and the gate electrode GE. The gate insulating layer GI may block electrical connection between the semiconductor layer ACT and the gate electrode GE. For example, the gate insulating layer GI may block direct electrical conduction between the gate and the channel region, and the gate electrode GE may be used control the channel region. The gate insulating layer GI may include inorganic materials such as silicon oxide, silicon nitride, and/or silicon oxynitride.

The interlayer insulating layer LI may be disposed above the gate electrode GE. The interlayer insulating layer LI may include inorganic materials such as silicon oxide, silicon nitride, and/or silicon oxynitride. The source electrode SE and drain electrode DE may be disposed on the interlayer insulating layer LI.

A planarization layer FL may be disposed on the transistors TFT. In an embodiment, after forming the planarization layer FL, chemical and/or mechanical polishing may be performed on the upper surface of the planarization layer FL to provide a flat upper surface. The planarization layer FL may include photosensitive polyimide, polyimide, polystyrene (PS), polycarbonate (PC), benzocyclobutene (BCB), hexamethyldisiloxane (HMDSO), polymethylmethacrylate (PMMA), general-purpose polymers such as polystyrene (PS), polymer derivatives having phenolic groups, acrylic polymers, imide-based polymers, arylether-based polymers, amide-based polymers, fluorinated polymers, p-xylene-based polymers, or vinyl alcohol-based polymers.

The planarization layer FL may include a single layer or a multilayer structure. Disposed on the planarization layer FL may be organic light-emitting diodes (OLED) including the first organic light-emitting diode OLED1, the second organic light-emitting diode OLED2, and the third organic light-emitting diode OLED3. The first organic light-emitting diode OLED1 may include a first pixel electrode EL1, a first middle layer MFL1, and a counter electrode EL2; the second organic light-emitting diode OLED2 may include a second pixel electrode EL1′, a second middle layer MFL2, and a counter electrode EL2; and the third organic light-emitting diode OLED3 may include a third pixel electrode EL1″, a third middle layer MFL3, and a counter electrode EL2. Since the first organic light-emitting diode OLED1, the second organic light-emitting diode OLED2, and the third organic light-emitting diode OLED3 have substantially the same or similar structure, the following description will focus on the structure of the first organic light-emitting diode OLED1, and redundant explanations may be omitted or simplified.

The first pixel electrode EL1 may be disposed on the planarization layer FL. The first pixel electrode EL1, the second pixel electrode EL1′, and the third pixel electrode EL1″ may be spaced apart from each other and correspond to each pixel.

The first pixel electrode EL1 may be a reflective electrode. For example, the first pixel electrode EL1 may include a reflective layer comprising silver (Ag), magnesium (Mg), aluminum (Al), platinum (Pt), palladium (Pd), gold (Au), nickel (Ni), neodymium (Nd), iridium (Ir), or chromium (Cr), or compounds thereof, and a transparent or semi-transparent conductive layer. The transparent or semi-transparent conductive layer may include a material including one or more of indium tin oxide (ITO), indium zinc oxide (IZO), zinc oxide (ZnO), indium oxide (In₂O₃), indium gallium oxide (IGO), or aluminum zinc oxide (AZO). For example, the first pixel electrode EL1 may have a structure stacked with ITO/Ag/ITO. The second pixel electrode EL1′ and the third pixel electrode EL1″ may be made of the same material as the first pixel electrode EL1.

A pixel defining layer PDL may be disposed on the first pixel electrode EL1, the second pixel electrode EL1′, and the third pixel electrode EL1″. The pixel defining layer PDL may be patterned to have a first pixel opening OP1, a second pixel opening OP2, and a third pixel opening OP3. The first pixel opening OP1, the second pixel opening OP2, and the third pixel opening OP3 may respectively, correspond to a plurality of light-emitting regions. For example, the first pixel opening OP1 may correspond to a first light-emitting region EA1, the second pixel opening OP2 may correspond to a second light-emitting region EA2, and the third pixel opening OP3 may correspond to a third light-emitting region EA3. The first pixel opening OP1, the second pixel opening OP2, and the third pixel opening OP3 may respectively, expose the central portions of the first pixel electrode EL1, the second pixel electrode EL1′, and the third pixel electrode EL1″. The pixel defining layer PDL may cover the edges of the first pixel electrode EL1, the second pixel electrode EL1′, and the third pixel electrode EL1″ to increase the distance between the edges of the pixel electrodes and the counter electrode EL2, thereby being configured to prevent the occurrence of arcing or similar issues.

The pixel defining layer PDL may include an organic insulating material. Alternatively, the pixel defining layer PDL may include an inorganic insulating material such as silicon nitride, silicon oxynitride, or silicon oxide. The pixel defining layer PDL may also include both organic and inorganic insulating materials.

In an embodiment, the pixel defining layer PDL may include a light-blocking material. For example, the light-blocking material may be black in color. The light-blocking material may include carbon black, carbon nanotubes, a resin or paste containing black dye, metal particles such as nickel, aluminum, molybdenum, or their alloys, metal oxide particles (e.g., chromium oxide), or metal nitride particles (e.g., chromium nitride). In the case where the pixel defining layer PDL includes a light-blocking material, the pixel defining layer PDL may reduce the reflection of external light caused by the metal structures disposed beneath the pixel defining layer PDL. Nevertheless, the present disclosure is not limited thereto. In another embodiment, the pixel defining layer PDL may not include a light-blocking material and may instead include a light-transmitting organic insulating material.

A spacer SP may be disposed on the pixel defining layer PDL. The spacer SP may support a mask during the manufacturing process of the first to third light-emitting layers EML, EML′, and EML″. The spacer SP may include an organic insulating material such as polyimide. A Iternatively, the spacer SP may include an inorganic insulating material such as silicon nitride (SINx) or silicon oxide (SiO₂), or may include both organic and inorganic insulating materials. In an embodiment, the spacer SP may be made of the same material as the pixel defining layer PDL. In such a case, the pixel defining layer PDL and the spacer SP may be formed together during a mask process using a half-tone mask or the like. In another embodiment, the spacer SP and the pixel defining layer PDL may include different materials.

A first middle layer MFL may be disposed on the first pixel electrode EL1, a second middle layer MFL′ may be disposed on the second pixel electrode EL1′, and a third middle layer MFL″ may be disposed on the third pixel electrode EL1″. In an embodiment, the first middle layer MFL may include a first light-emitting layer EML capable of emitting first light in red, the second middle layer MFL′ may include a second light-emitting layer EML′ capable of emitting second light in blue, and the third middle layer MFL″ may include a third light-emitting layer EML″ capable of emitting third light in green.

The first light-emitting layer EML may be disposed in the first pixel opening OP1 of the pixel defining layer PDL, corresponding to the first pixel electrode EL1. The first light-emitting layer EML may be an organic material that includes a fluorescent or phosphorescent substance capable of emitting red light. The organic material may be a small-molecule organic material or a polymer organic material. Alternatively, the first light-emitting layer EML may be an inorganic material that includes, for example, quantum dots. Specifically, quantum dots refer to crystals of a semiconductor compound and may include any material capable of emitting light at various emission wavelengths depending on the size of the crystal. Quantum dots may include, for example, Group III-VI semiconductor compounds, Group II-VI semiconductor compounds, Group III-V semiconductor compounds, Group I-III-VI semiconductor compounds, Group IV-VI semiconductor compounds, or Group IV elements or compounds, or any combination thereof.

Similarly, the second light-emitting layer EML′ may be disposed in the second pixel opening OP2 of the pixel defining layer PDL, and the third light-emitting layer EML″ may be disposed in the third pixel opening OP3 of the pixel defining layer PDL. The second light-emitting layer EML′ may be an organic material that includes a fluorescent or phosphorescent substance capable of emitting blue light. The third light-emitting layer EML″ may be an organic material that includes a fluorescent or phosphorescent substance capable of emitting green light.

A first common layer CML1 may be disposed below each of the first light-emitting layer EML, the second light-emitting layer EML′, and the third light-emitting layer EML″. A second common layer CML2 may be disposed above each of the first light-emitting layer EML, the second light-emitting layer EML′, and the third light-emitting layer EML″. The first common layer CML1 may include, for example, a hole transport layer HTL or both a hole transport layer and a hole injection layer HIL. The second common layer CML2 may include, for example, an electron transport layer ETL or both an electron transport layer and an electron injection layer EIL. In an embodiment, the second common layer CML2 may be omitted.

The first light-emitting layer EML, the second light-emitting layer EML′, and the third light-emitting layer EML″ may be patterned to correspond to the first pixel opening OP1, the second pixel opening OP2, and the third pixel opening OP3 of the pixel defining layer PDL, respectively. In contrast, the first common layer CML1 and the second common layer CML2 may each be integrally formed to cover the entire substrate SS. For example, the first common layer CML1 and the second common layer CML2 may each be integrally formed to entirely cover the first pixel electrode EL1, the second pixel electrode EL1′, and the third pixel electrode EL1″, which are disposed in the display area DA (see FIG. 1).

The counter electrode EL2 may be disposed on the first middle layer MFL. The counter electrode EL2 may include a conductive material with a low work function. For example, the counter electrode EL2 may include a (semi-)transparent layer containing silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or ytterbium (Yb), or alloys thereof. In an example, the counter electrode EL2 may be AgMg or AgYb. Alternatively, the counter electrode EL2 may further include a layer of ITO, IZO, ZnO, or In₂O₃ on the (semi-)transparent layer containing the aforementioned materials.

The layers from the first pixel electrode EL1 to the counter electrode EL2 may form the first organic light-emitting diode (OLED1), the layers from the second pixel electrode EL1′ to the counter electrode EL2 may form the second organic light-emitting diode (OLED2), and the layers from the third pixel electrode EL1″ to the counter electrode EL2 may form the third organic light-emitting diode (OLED3).

In an embodiment, the display device may further include a capping layer disposed on the first organic light-emitting diode (OLED1), the second organic light-emitting diode (OLED2), and the third organic light-emitting diode (OLED3). The capping layer may be integrally formed to entirely cover the counter electrode EL2. The capping layer may be configured to enhance the light-emission efficiency of the organic light-emitting diodes (OLEDs) through the principle of constructive interference.

The capping layer may be an organic capping layer including organic materials, an inorganic capping layer including inorganic materials, or a composite capping layer including both organic and inorganic materials. For example, the capping layer may include carbocyclic compounds, heterocyclic compounds, amine group-containing compounds, porphine derivatives, phthalocyanine derivatives, naphthalocyanine derivatives, alkali metal complexes, alkaline earth metal complexes, or any combination thereof. The carbocyclic compounds, heterocyclic compounds, and amine group-containing compounds may optionally be substituted with substituents containing elements including O, N, S, Se, Si, F, Cl, Br, or I, or any combination thereof.

An encapsulation layer EN may be disposed on the display layer DL. For example, at least a portion of the display layer DL may be sealed by the encapsulation layer EN. The encapsulation layer EN may include at least one inorganic encapsulation layer and at least one organic encapsulation layer.

The inorganic encapsulation layer may include inorganic insulating materials such as silicon oxide, silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO). The inorganic encapsulation layer may have a single-layer or multi-layer structure containing the aforementioned inorganic insulating materials.

The organic encapsulation layer may reduce an internal stress of the inorganic encapsulation layer. The organic encapsulation layer may include polymer-based materials. Examples of polymer-based materials may include polyethylene terephthalate, polyethylene naphthalate, polycarbonate, polyimide, polyethylene sulfonate, polyoxymethylene, polyarylate, hexamethyldisiloxane, or acrylic resins (e.g., polymethyl methacrylate, polyacrylic acid), or any combination thereof.

The organic encapsulation layer may be formed by applying a material that has flowability and contains monomers, and inducing a reaction using heat or light, such as ultraviolet light, to cause the monomers to bond and form a polymer. Alternatively, the organic encapsulation layer may be formed by applying a polymer material.

The encapsulation layer EN, with a multilayer structure as described herein, can inhibit or prevent cracks that occur within the encapsulation layer EN from propagating between the inorganic encapsulation layer and the organic encapsulation layer. The encapsulation layer EN, with a multilayer structure may prevent or minimize the formation of pathways through which external moisture or oxygen may penetrate into the display area DA. Additionally, by adjusting the thickness of each layer in the encapsulation layer EN, the reflectivity for different wavelength bands of external light can be varied, enabling an adjustment of the reflective color of the display device. The encapsulation layer EN may also provide a flat base surface for the touch sensing layer TSL, which may be disposed on top of the encapsulation layer EN.

The touch sensing layer TSL may be disposed on the encapsulation layer EN. The touch sensing layer TSL may include a first electrode MTL1, a touch insulation layer TIL, a second electrode MTL2, and a protective layer PVX. The first electrode MTL1 may be directly disposed on the encapsulation layer EN. In such a case, the first electrode MTL1 may be directly disposed on, but not limited to, the inorganic encapsulation layer of the encapsulation layer EN.

For example, the touch sensing layer TSL may further include an insulating layer disposed between the first electrode MTL1 and the encapsulation layer EN. The insulating layer may be disposed on the inorganic encapsulation layer of the encapsulation layer EN, providing a flat base surface for the first electrode MTL1 and the like. In this case, the first electrode MTL1 may be directly disposed on the insulating layer. The insulating layer may include inorganic insulating materials such as silicon oxide (SiO₂), silicon nitride (SiNx), or silicon oxynitride (SiON). Alternatively, the insulating layer may include organic insulating materials.

A second electrode MTL2 may be disposed on the first electrode MTL1. In an embodiment of the present disclosure, the first electrode MTL1 may function as the connection electrode BE, as described with reference to FIG. 3. The second electrode MTL2 may function as the sensing electrode RE and the driving electrode TE, as described with reference to FIG. 3. In an embodiment of the present disclosure, at the connection between the connection electrode BE and the driving electrode TE, the first electrode MTL1 and the second electrode MTL2 may be electrically connected through a touch contact hole TCNT that penetrates the touch insulation layer TIL. In an embodiment of the present disclosure, the first electrode MTL1 and the second electrode MTL2 may have a mesh structure, which may allow light emitted from the first organic light-emitting diode OLED1, the second organic light-emitting diode OLED2, and the third organic light-emitting diode OLED3 to pass through. In such a case, the first electrode MTL1 and the second electrode MTL2 may be disposed in non-emission regions NA and may not overlap with the first light-emitting region EA1, the second light-emitting region EA2, and the third light-emitting region EA3.

The first electrode MTL1 and the second electrode MTL2 may include a metal layer or a transparent conductive layer. The metal layer may include molybdenum (Mo), silver (Ag), titanium (Ti), copper (Cu), or aluminum (Al), or alloys thereof. The transparent conductive layer may include transparent conductive oxides such as indium tin oxide (ITO), indium zinc oxide (IZO), zinc oxide (ZnO), or indium tin zinc oxide (ITZO). Additionally, the transparent conductive layer may include conductive polymers such as PEDOT, metal nanowires, carbon nanotubes, or graphene.

The touch insulation layer TIL may be disposed between the first electrode MTL1 and the second electrode MTL2. The touch insulation layer TIL may overlap with the second light-emitting region EA2 of the second organic light-emitting diode OLED2. The touch insulation layer TIL may not overlap with the first light-emitting region EA1 of the first organic light-emitting diode OLED1 and the third light-emitting region EA3 of the third organic light-emitting diode OLED3. For example, the touch insulation layer TIL may expose the first light-emitting region EA1 of the first organic light-emitting diode OLED1 and the third light-emitting region EA3 of the third organic light-emitting diode OLED3. Accordingly, the red first light emitted from the first organic light-emitting diode OLED1 and the green third light emitted from the third organic light-emitting diode OLED3 may be emitted without passing through the touch insulation layer TIL.

The touch insulation layer TIL may be provided with an organic layer that includes a colorant, such as a dye, pigment, or a combination thereof, which may absorb certain wavelength bands of visible light. For example, the touch insulation layer TIL may be formed by applying a polymer including a blue colorant. In such a case, the touch insulation layer TIL may be configured to transmit the blue second light emitted from the second organic light-emitting diode OLED2 while absorbing light of wavelengths other than blue. The touch insulation layer TIL may be configured to transmit the blue second light with improved color purity. The colorant included in the touch insulation layer TIL may include, but not limited to, Pigment Blue 15 (C.I. Pigment 15). For example, the colorant included in the touch insulation layer TIL may include a compound represented by Chemical Formula 1. Chemical Formula 1 may represent the structure of Pigment Blue 15 (C.I. Pigment 15). Chemical Formula 1 is provided as an example, and the present disclosure is not limited thereto.

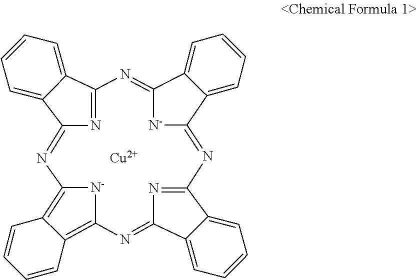

The touch insulation layer TIL may include polyethylene terephthalate, polyethylene naphthalate, polycarbonate, polyimide, polyethylene sulfonate, polyoxymethylene, polyarylate, hexamethyldisiloxane, or acrylic resins (e.g., polymethyl methacrylate, polyacrylic acid), or combinations thereof as a base polymer.

The protective layer PVX may be disposed on the second electrode MTL2 and the touch insulation layer TIL. In an embodiment, the protective layer PV X may cover the second electrode MTL2 and the touch insulation layer TIL. The protective layer PVX may provide a flat base surface for the reflection adjustment layer RCL, as described herein. The protective layer PVX may include polyethylene terephthalate, polyethylene naphthalate, polycarbonate, polyimide, polyethylene sulfonate, polyoxymethylene, polyarylate, hexamethyldisiloxane, acrylic resins (e.g., polymethyl methacrylate, polyacrylic acid), or combinations thereof as a base polymer. The protective layer PVX may not contain a colorant, in contrast to the touch insulation layer TIL. However, the present embodiment is not limited thereto. For example, the protective layer PVX may include a colorant that has a different color from the colorant included in the touch insulation layer TIL.

The reflection adjustment layer RCL may be disposed on the touch sensing layer TSL. In an embodiment, the reflection adjustment layer RCL may be directly disposed, but not limited to, on the protective layer PVX. The reflection adjustment layer RCL may include a first adjustment portion RC1, where the transmitted light is non-polarized, and a second adjustment portion RC2, where the transmitted light is polarized. The first adjustment portion RC1 may have a higher transmittance than the second adjustment portion RC2. The first adjustment portion RC1 may overlap with and cover the second light-emitting region EA2. The second adjustment portion RC2 may overlap with and cover the first light-emitting region EA1 and the third light-emitting region EA3. The light passing through the first adjustment portion RC1 may be non-polarized, the loss of transmitted light may be minimized. Meanwhile, the light passing through the second adjustment portion RC2 is polarized, and the reflection of external light may be prevented.

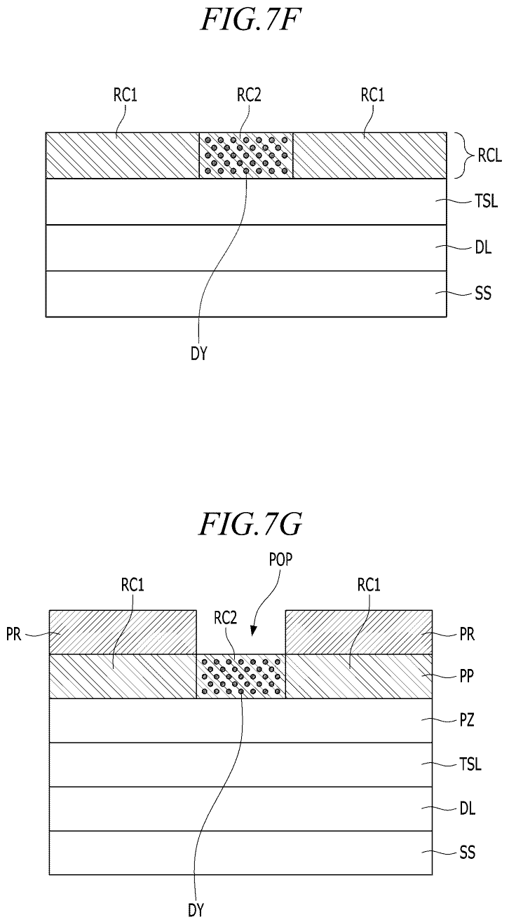

A phase delay layer may be further disposed on a side of the reflection adjustment layer RCL. For example, the reflection adjustment layer RCL may be disposed on the phase delay layer (see phase delay layer PZ, FIG. 7G). The phase delay layer may be configured to convert linear polarized light into circular polarized light and vice versa. For example, external light incident on the second adjustment portion RC2 of the reflection adjustment layer RCL may be linearly polarized by the second adjustment portion RC2 and circularly polarized by the phase delay layer. The circular polarized external light may be reflected within the display device, becoming reflected light, during which the phase and polarization axis may be altered. The reflected light with the changed phase may not pass through the second adjustment portion RC2, and the reflection of external light can be reduced or prevented by the second adjustment portion RC2. Therefore, a larger amount of light can pass through the first adjustment portion RC1 than through the second adjustment portion RC2, resulting in the first adjustment portion RC1 having a higher transmittance than the second adjustment portion RC2.

The phase delay layer may be a λ/4 phase delay layer and/or a λ/2 phase delay layer. For example, a λ/4 phase delay layer and a λ/2 phase delay layer may be successively disposed on the touch sensing layer TSL. Such a phase delay layer is not limited to any particular form, as long as it is commonly known in the art. For instance, the phase delay layer may be provided in the form of a stretched polymer film obtained from materials such as polycarbonate, polyvinyl alcohol, polystyrene, polymethyl methacrylate, polypropylene, polyolefin, polyarylate, or polyamide.

In an embodiment, the λ/4 phase delay layer and/or the λ/2 phase delay layer may be a liquid crystal-coated phase delay layer. The λ/4 phase delay layer and/or the λ/2 phase delay layer may include a reactive liquid crystal monomer (e.g., a calamitic mesogen exhibiting a nematic liquid crystal phase), and the alignment layer may include polyimide or polyamide. In an embodiment, the liquid crystal layer of the λ/4 phase delay layer and/or the λ/2 phase delay layer may include a photo-reactive polymer having refractive index anisotropy, in which case the alignment layer may be omitted.

In an embodiment, the width TD of the first adjustment portion RC1 may be greater than a width ETD of the second light-emitting region EA2. Specifically, the width of the first adjustment portion RC1 may be smaller than a limiting width LTD, which may be the distance between centers of the pixel defining layers PDL that define the second pixel opening OP2, but larger than the width ETD of the second light-emitting region EA2.

The width TD of the first adjustment portion RC1 may be formed larger than the width ETD of the second light-emitting region EA2, allowing an increase in the amount of light passing through the first adjustment portion RC1 from the second organic light-emitting diode OLED2 compared to when the width TD of the first adjustment portion RC1 is the same as the width ETD of the second light-emitting region EA 2. Specifically, light emitted from the second organic light-emitting diode OLED2 can be not only emitted within the second pixel opening OP2 but also emitted at an oblique angle beyond the width of the second pixel opening OP2 in the third direction. Therefore, the width TD of the first adjustment portion RC1 in the display device DD according to an embodiment may be formed larger than the width ETD of the second light-emitting region EA2, reducing the amount of light emitted from the second organic light-emitting diode OLED2 that is incident on the second adjustment portion RC2 and thereby improving the light-emission efficiency of the second organic light-emitting diode OLED2.

Meanwhile, the width TD of the first adjustment portion RC1 may be formed smaller than the limiting width LTD, so that the light emitted from the first organic light-emitting diode OLED1 and the third organic light-emitting diode OLED3 may not enter the first adjustment portion RC1. For example, the width TD of the first adjustment portion RC1 may be adjusted within the range between the limiting width LTD and the width ETD of the second light-emitting region EA2 in the display device DD according to an embodiment.

The reflection adjustment layer RCL may include liquid crystals and a dichroic dye. Specifically, the first adjustment portion RC1 may be a region that includes liquid crystals, and the second adjustment portion RC2 may be a region that includes liquid crystals and a dichroic dye. In such a case, the liquid crystals in both the first adjustment portion RC1 and the second adjustment portion RC2 may be formed from the same liquid crystal material. In an embodiment, the first adjustment portion RC1 and the second adjustment portion RC2 may share a single liquid crystal compound layer formed through a single process.

The second adjustment portion RC2 may further include a dichroic dye in addition to the liquid crystals. The dichroic dye may be oriented in the same direction as the aligned liquid crystals. The dichroic dye, oriented in the liquid crystal direction, may linearly polarize the transmitted light. Therefore, the light passing through the second adjustment portion RC2 may become linearly polarized. The first adjustment portion RC1 and the second adjustment portion RC2 may be distinguished by the presence or absence of the dichroic dye. Specifically, the first adjustment portion RC1 may be the region of the reflection adjustment layer RCL that does not include the dichroic dye, while the second adjustment portion RC2 may be the remaining region of the reflection adjustment layer RCL that includes the dichroic dye.

In an embodiment, the first adjustment portion RC1 and the second adjustment portion RC2 may have an integrated shape. For example, the reflection adjustment layer RCL may be uniformly deposited on an upper surface of the touch sensing layer TSL. For example, the reflection adjustment layer RCL may include a deposited material, and the first adjustment portion RC1 and the second adjustment portion RC2 may be formed from the deposited material. For example, the reflection adjustment layer RCL may include a single liquid crystal layer formed through a single process, with the second adjustment portion RC2 being formed by dyeing the layer with a dichroic dye, and the remaining region being defined as the first adjustment portion RC1. For example, the reflection adjustment layer RCL may be a patterned polarizer including a non-polarized portion corresponding to the first adjustment portion RC1 and a polarized portion corresponding to the second adjustment portion RC2.

In an embodiment, the first adjustment portion RC1 may overlap with the second light-emitting region EA2 corresponding to the second organic light-emitting diode OLED2. Therefore, the second organic light-emitting diode OLED2 may overlap with the second light-emitting region EA2, the touch insulation layer TIL, and the first adjustment portion RC1.

In an embodiment, the second organic light-emitting diode OLED2 may emit blue light, and the emitted blue light may pass through the touch insulation layer TIL. The touch insulation layer TIL may include a colorant may selectively transmits light. The light having passed through the touch insulation layer TIL may then pass through the first adjustment portion RC1. External light incident into the first adjustment portion RC1 may not be polarized, and when this external light reaches the touch insulation layer TIL, specific wavelength bands may pass through, while other wavelength bands may be absorbed, depending on the type of colorant included in the touch insulation layer TIL.

In an embodiment, external light incident into the first adjustment portion RC1 may not be polarized, and when this external light reaches the touch insulation layer TIL, blue light may pass through, while light of other wavelengths may be absorbed. The blue light having passed through the touch insulation layer TIL may be reflected inside the display device DD and re-emitted externally. External light incident into the second adjustment portion RC2 may be linearly polarized, thereby inhibiting or preventing external light reflection and improving visibility.

Although the first adjustment portion RC1 may be formed to overlap with the second light-emitting region EA2, where blue light is emitted, and where the touch insulation layer TIL selectively transmits blue light, the present disclosure is not limited thereto. In another embodiment, a touch insulation layer TIL that selectively transmits red light may be disposed to overlap with the first light-emitting region EA1, and the first adjustment portion RC1 may overlap with the touch insulation layer TIL. In such a case, the first adjustment portion RC1 and the touch insulation layer TIL may not overlap with the second light-emitting region EA2 and the third light-emitting region EA3. For example, the first adjustment portion RC1 and the touch insulation layer TIL may expose the second light-emitting region EA2 and the third light-emitting region EA3. In yet another embodiment, the first adjustment portion RC1 may overlap with the third light-emitting region EA3, where green light is emitted, and where the touch insulation layer may selectively transmits green light. In such a case, the first adjustment portion RC1 and the touch insulation layer TIL may not overlap with the first light-emitting region EA1 or the second light-emitting region EA2. For example, the first adjustment portion RC1 and the touch insulation layer TIL may expose the first light-emitting region EA1 or the second light-emitting region EA2

In an embodiment, a phase delay layer may be disposed below the reflection adjustment layer RCL, and external light incident into the second adjustment portion RC2 may be linearly polarized by the second adjustment portion RC2 and then circularly polarized by the phase delay layer. The phase and polarization axis of the circularly polarized external light, which may be reflected inside the display device and becomes reflected light, are varied during the reflection process. As a result, the reflected light with the changed phase may not pass through the second adjustment portion RC2, thereby inhibiting or preventing the reflection of external light by the second adjustment portion RC2, which in turn can improve the visibility of the display device DD.

The liquid crystals included in the reflection adjustment layer RCL may be of the lyotropic type or the host-guest type. The lyotropic type liquid crystal material may be formed when a material (e.g., amphiphilic molecules like surfactants, lipids, or block copolymers) is mixed with a solvent, such as water or another polar solvent. The liquid crystal phase may emerge due to self-assembly of these molecules at specific concentrations and temperatures. The host-guest type liquid crystal system may include guest molecules introduced into a liquid crystal host to modify or enhance an optical, electrical, or thermal property. The guest molecules can be dyes, dopants, or other functional additives that interact with the liquid crystal host to achieve an effects. However, the present disclosure is not limited thereto. In an embodiment, the lyotropic liquid crystal may be a compound represented by, but not limited to, any one of Chemical Formulas 2 to 5.

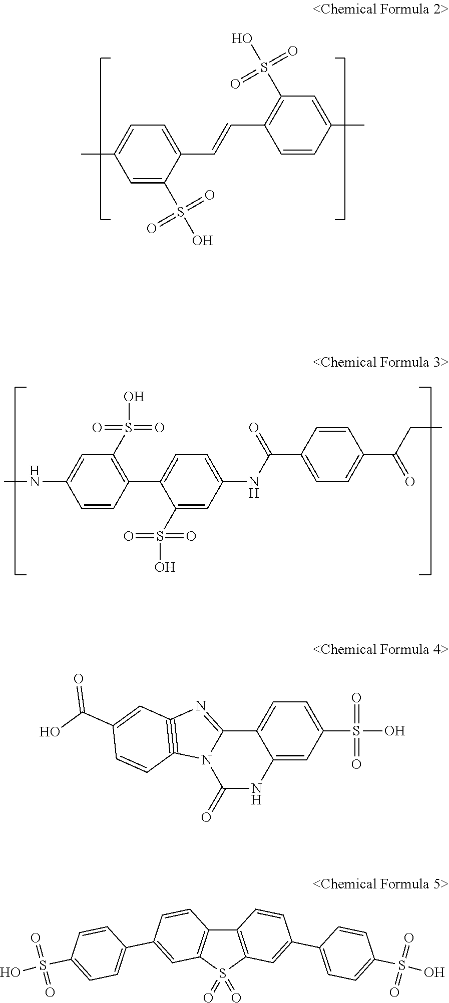

In an embodiment, the host-guest type liquid crystal may be a compound represented by, but not limited to, any one of Chemical Formulas 6 to 8.

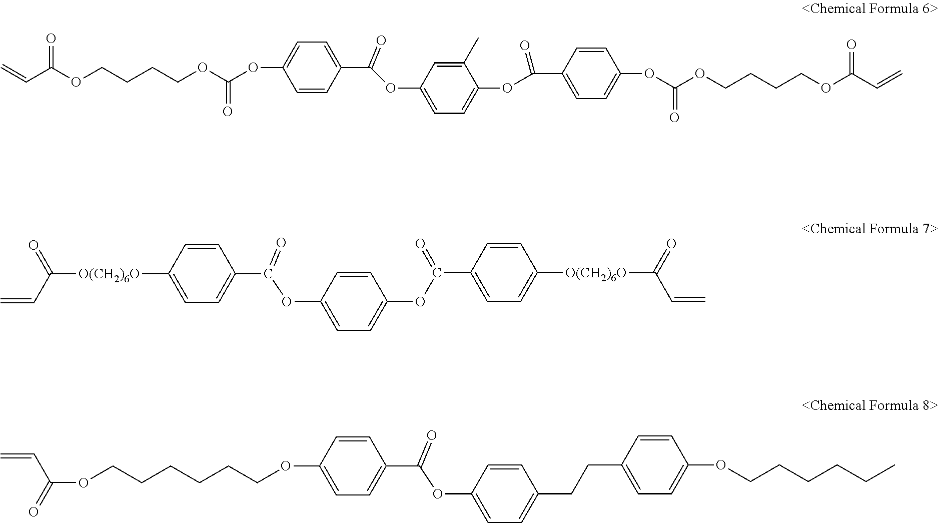

In an embodiment, when the liquid crystal included in the reflection adjustment layer RCL is a lyotropic type liquid crystal, the dichroic dye included in the second adjustment portion RC2 may be a compound represented by, but not limited to, any one of Chemical Formulas 9 to 13.

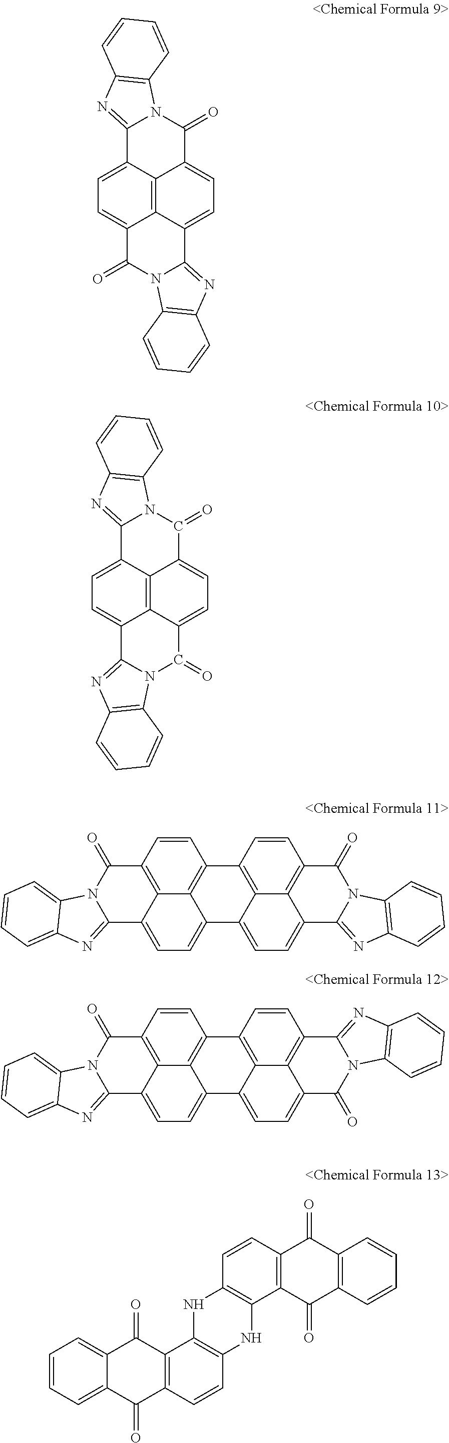 [SMILES: O=c1c2ccc3c4c(ccc(c24)c2nc4ccccc4n12)c(=O)n1c2ccccc2nc31 ; O=c1c2ccc3c(=O)n4c5ccccc5nc4c4ccc(c2c34)c2nc3ccccc3n12 ; O=c1c2ccc3c4ccc5c(=O)n6c7ccccc7nc6c6ccc(c7ccc(c2c37)c2nc3ccccc3n12)c4c56 ; O=c1c2ccc3c4ccc5c6c(ccc(c7ccc(c2c37)c2nc3ccccc3n12)c46)c(=O)n1c2ccccc2nc51 ; O=c1c2ccccc2c(=O)c2c1ccc1[nH]c3c(ccc4c(=O)c5ccccc5c(=O)c43)[nH]c12]

In an embodiment, when the liquid crystal included in the reflection adjustment layer RCL is a guest-host type liquid crystal, the dichroic dye included in the second adjustment portion RC2 may be a compound represented by, but not limited to, any one of Chemical Formulas 14 to 17.

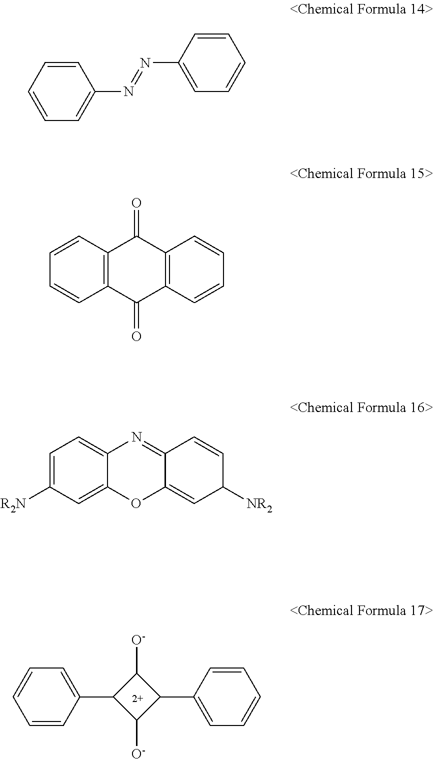

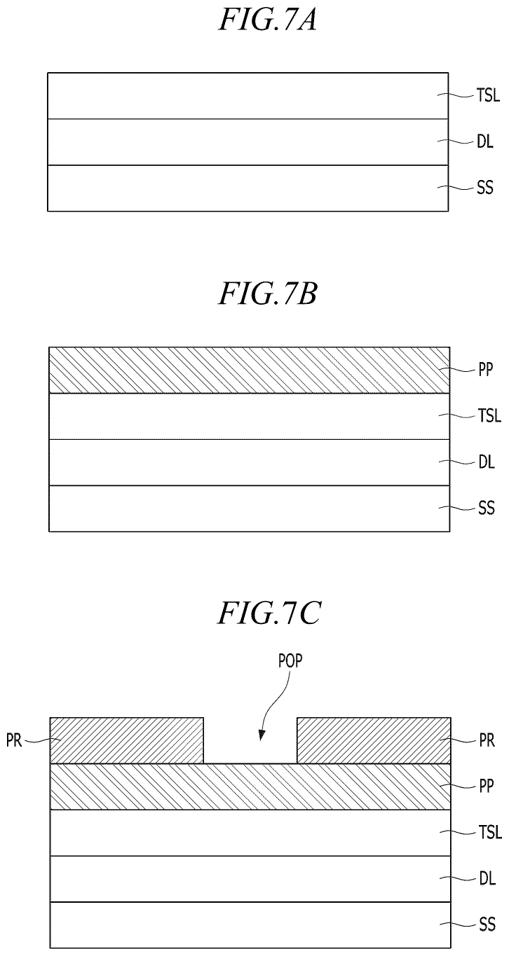

FIG. 5 is a graph illustrating the light transmittance of touch insulation layer samples. Referring to FIG. 5, the transmittance of light through the touch insulation layer may vary depending on a concentration of the colorant included in the touch insulation layer for different wavelength bands. For example, the first sample TIL1 may have a higher colorant concentration than the second sample TIL2, and the second sample TIL2 may have a higher colorant concentration than the third sample TIL3. The first sample TIL1 shows a relatively higher transmittance in the blue wavelength band (420-450 nm) compared to the second sample TIL2 and the third sample TIL3, and may also have a relatively high transmittance in the red wavelength band (630-750 nm). Conversely, the third sample TIL3 shows a relatively lower transmittance in the blue wavelength band compared to the second sample TIL2 and the first sample TIL1, and may also have a low transmittance in the red wavelength band, allowing for the representation of blue light with high color purity.

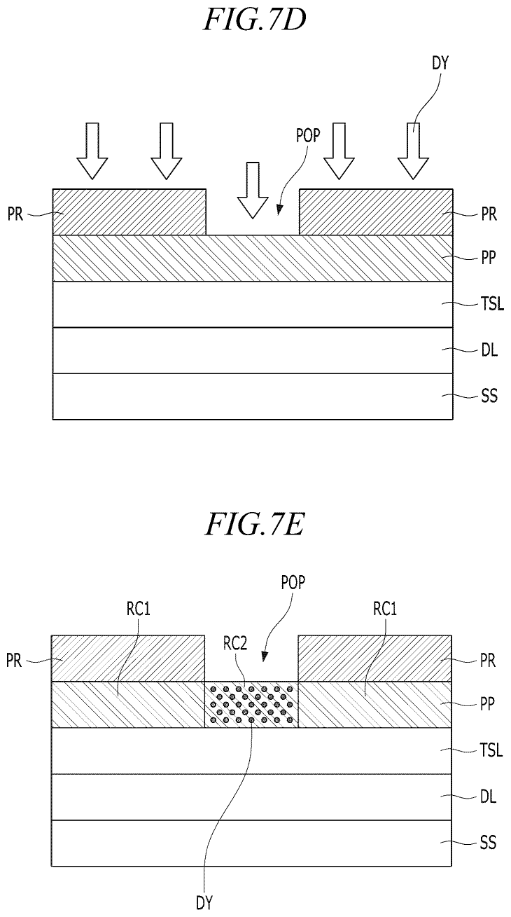

FIG. 6 is a flowchart illustrating a method of manufacturing a display device according to an embodiment of the present disclosure. FIGS. 7A, 7B, 7C, 7D, 7E, and to 7F are cross-sectional views sequentially illustrating part of the manufacturing method for a display device according to an embodiment of the present disclosure. A method of manufacturing the display device in an embodiment will be described with reference to FIG. 6. The same reference numerals will be used for the components described with reference to FIGS. 1 to 4, and detailed explanations of those components will be omitted.

Referring to FIG. 4, FIG. 5 and FIG. 6, a method for manufacturing a display device according to an embodiment of the present disclosure may include: preparing a display panel (S100); forming a touch sensing layer (S200); and forming a reflection adjustment layer (S300).

A step of preparing the display panel (S100) may include forming a display layer DL on a substrate SS and forming an encapsulation layer EN. A step of forming the display layer DL may include forming a pixel defining layer PDL, which may include a first pixel opening OP1, a second pixel opening OP2, and a third pixel opening OP3. A first light-emitting region EA1, a second light-emitting region EA2, and a third light-emitting region EA3 may each be defined by the first pixel opening OP1, the second pixel opening OP2, and the third pixel opening OP3, respectively.

A step of forming the display layer DL may include: forming a first organic light-emitting diode OLED1, which may correspond to the first light-emitting region EA1 and includes a first pixel electrode EL1, a first light-emitting layer EML, and a first middle layer MFL; forming a second organic light-emitting diode OLED2, which may correspond to the second light-emitting region EA2 and includes a second pixel electrode EL1′, a second light-emitting layer EML′, and a second middle layer MFL′; and forming a third organic light-emitting diode OLED3, which may correspond to the third light-emitting region EA3 and includes a third pixel electrode EL1″, a third light-emitting layer EML″, and a third middle layer MFL″.

In a step of forming the encapsulation layer EN, the encapsulation layer EN may be formed on the display layer DL to seal the display layer DL. A step of forming the touch sensing layer (S200) may include forming a first electrode MTL1, a touch insulation layer TIL, a second electrode MTL2, and a protective layer PVX on the encapsulation layer EN.

In an embodiment of the present disclosure, the first electrode MTL1 may be directly disposed on the encapsulation layer EN. The first electrode MTL1 and the second electrode MTL2 may be disposed in a non-emission region NEA and may not overlap with the first light-emitting region EA1, the second light-emitting region EA2, or the third light-emitting region EA3. The touch insulation layer TIL may be formed on the first electrode MTL1 and the encapsulation layer EN, and the touch insulation layer TIL may be formed between the first electrode MTL1 and the second electrode MTL2.

In an embodiment, the touch insulation layer TIL may be formed to overlap with the second light-emitting region EA2 of the second organic light-emitting diode OLED2. The touch insulation layer TIL may not overlap with the first light-emitting region EA1 of the first organic light-emitting diode OLED1 or the third light-emitting region EA3 of the third organic light-emitting diode OLED3.

In an embodiment of the present disclosure, the touch insulation layer TIL may be formed as an organic layer containing a colorant. The touch insulation layer TIL that includes a colorant may selectively transmit blue light.

The second electrode MTL2 may be formed on the touch insulation layer TIL. The second electrode MTL2 may be electrically connected to the first electrode MTL1 through a touch contact hole TCNT formed in the touch insulation layer TIL.

A step of forming the reflection adjustment layer (S300) may include providing a liquid crystal compound on the touch sensing layer TSL and dyeing a dichroic dye.

In an embodiment of the present disclosure, a step of providing the liquid crystal compound may be carried out using either a lyotropic type liquid crystal or a host-guest type liquid crystal. In an embodiment, a step of providing the liquid crystal compound may involve coating a lyotropic type liquid crystal that is self-aligned in the coating direction onto the touch sensing layer TSL. In such a case, the liquid crystal compound may be provided on the touch sensing layer TSL in a single process, forming a single liquid crystal layer.

In an embodiment, a step of coating the lyotropic type liquid crystal may be carried out using, but not limited to, a bar coater or a slot die coater. In an embodiment, a step of providing the liquid crystal compound may include coating a host-guest type liquid crystal onto the touch sensing layer TSL and aligning the coated liquid crystal. In an embodiment, a step of aligning the coated host-guest type liquid crystal may be carried out through, but not limited to, photo-alignment or rubbing.

In an embodiment, the reflection adjustment layer RCL may include a first adjustment portion RC1 and a second adjustment portion RC2. The first adjustment portion RC1 may be a portion formed to overlap with and cover the second light-emitting region EA2, and the second adjustment portion RC2 may be a portion formed to overlap with the first light-emitting region EA1 and the third light-emitting region EA3 but not to overlap with the first light-emitting region EA1.

The second adjustment portion RC2 may be formed by dyeing a dichroic dye onto the liquid crystal provided on the touch sensing layer TSL. The first adjustment portion RC1 may be defined as the remaining region of the reflection adjustment layer RCL in which the dichroic dye is not dyed. For example, the first adjustment portion RC1 may be the region of the reflection adjustment layer RCL that is formed without including the dichroic dye, and the second adjustment portion RC2 may be the remaining region formed to include the dichroic dye.

FIG. 7A is a cross-sectional view sequentially illustrating a step of providing a dichroic dye according to an embodiment of the present disclosure.

In an embodiment, a step of providing the dichroic dye may include: forming a photoresist on the liquid crystal compound layer; exposing and developing the photoresist to form a dyeing pattern and expose a portion of the liquid crystal compound layer; dyeing the dichroic dye onto the dyeing pattern; and removing the photoresist.

Referring to FIG. 7A, FIG. 7B, and FIG. 7C, in a step of forming the photoresist PR, the photoresist PR may be formed on the liquid crystal compound layer PP, which may be formed on the touch sensing layer TSL. The photoresist PR may be then exposed and developed to form an exposed portion POP of the liquid crystal compound layer PP. In such a case, the exposed portion POP may be a region corresponding to the second adjustment portion RC2 (see FIG. 7E).

Referring to FIG. 7D and FIG. 7E, in a step of dyeing, the dichroic dye DY may be supplied onto the exposed portion POP of the liquid crystal compound layer PP so that the dichroic dye DY may be dyed onto the exposed portion POP of the liquid crystal compound layer PP, and the reflection adjustment layer RCL may be formed. For example, dyeing the liquid crystal compound layer PP may form a dyed pattern overlapping with a second light-emitting layer RC2 of the plurality of light-emitting layers and surrounding at least a portion of the first light-emitting layer RC1. The reflection adjustment layer RCL may include the second adjustment portion RC2, in which the dichroic dye DY is dyed, and the first adjustment portion RC1, in which no dye is applied.

Referring to FIG. 7F, in a step of removing the photoresist, the photoresist on the reflection adjustment layer RCL may be removed. With the photoresist removed, the reflection adjustment layer RCL may be formed including the second adjustment portion RC2 and the first adjustment portion RC1 surrounding the second adjustment portion RC2.

According to a method of manufacturing a display device in an embodiment of the present disclosure, a reflection adjustment layer with regions that polarize incident light and regions that do not polarize light may be directly formed on the touch sensing layer through a process of dyeing the liquid crystal compound with a dye.

Referring to FIG. 7G, a phase delay layer PZ may be further disposed on the touch sensing layer TSL. Further, the liquid crystal compound layer PP may be formed on the phase delay layer PZ. A method may continue according to FIGS. 7C to 7F, and a display device, including a phase delay layer PZ, in an embodiment of the present disclosure may be manufactured.

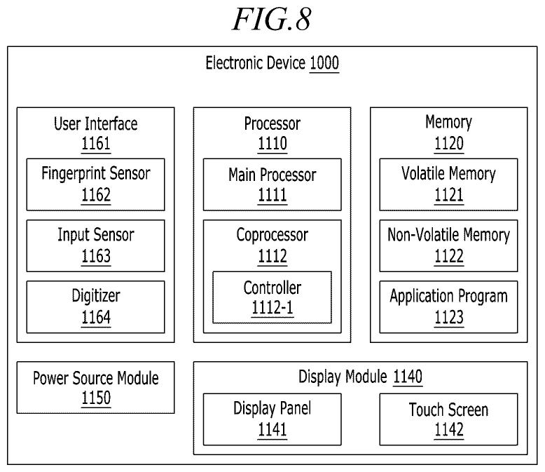

FIG. 8 is an exemplary block diagram of an electronic device according to an embodiment.

FIG. 8 is a diagram illustrating an electronic device according to an embodiment of the present invention. Referring to FIG. 8, the electronic device 1000 according to an embodiment of the present invention may output various information (e.g., images, text, music, etc.) through a display module 1140, which, for example, may correspond to the display device DD shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device DD shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

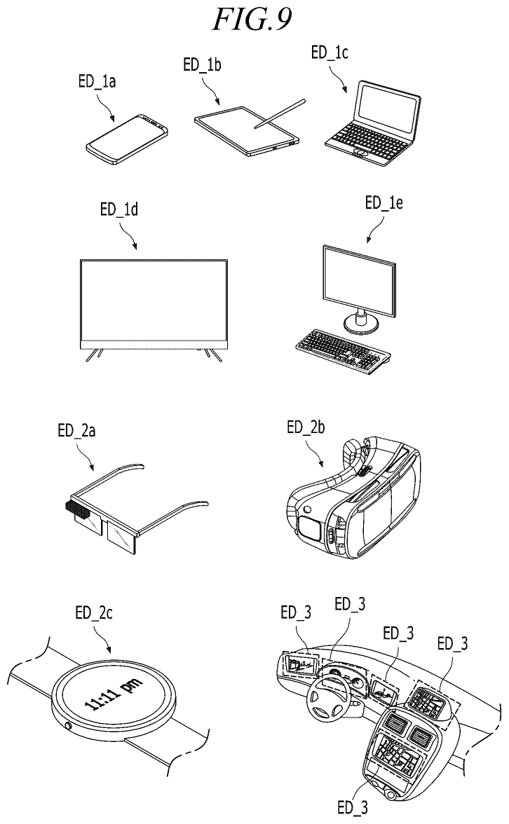

FIG. 9 illustrates schematic diagrams of electronic devices according to different embodiments.

Referring to FIG. 9, various electronic devices having display devices according to embodiments may include not only an image display electronic device, such as a smart phone ED-1a, a tablet PC ED-1b, a laptop ED-1c, a television ED-1d, or a desk monitor ED-1e, but also a wearable electronic device including a display module, such as smart glass ED-2a, a head mounted display ED-2b, or a smart watch ED-2c, or a vehicle electronic device ED-3 including a display module, such as a CID (Center Information Display) and a room mirror display disposed on an instrument panel, center fascia, or a dashboard of an automobile.

While embodiments of the present disclosure have been described herein, one ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that embodiments are not intended to restrict the present disclosure thereto and that every technical idea within the appended claims and their equivalents is interpreted to be included in the scope of the present disclosure.

What is claimed is:

1. A display device comprising:
a display panel in which a plurality of light-emitting regions configured for displaying images are defined;
a touch sensing layer disposed on the display panel; and
a reflection adjustment layer disposed on the touch sensing layer,
wherein the touch sensing layer comprises a touch insulation layer,
wherein, on a plane, the touch insulation layer covers a first light-emitting region of the plurality of light-emitting regions and exposes a second light-emitting region of the plurality of light-emitting regions,
wherein the touch insulation layer includes a colorant,
wherein the reflection adjustment layer comprises a first adjustment portion and a second adjustment portion, the first adjustment portion covering the first light-emitting region and the second adjustment portion covering the second light-emitting region, and
wherein the first adjustment portion is non-polarized, and the second adjustment portion is polarized.

2. The display device of claim 1, wherein the first adjustment portion and the second adjustment portion have an integrated shape.

3. The display device of claim 1, wherein the display panel is configured to emit light of a first wavelength band through the first light-emitting region,
wherein the touch sensing layer comprises a first electrode, a second electrode, and the touch insulation layer is disposed between the first electrode and the second electrode, and
wherein the touch insulation layer is configured to selectively transmit light of the first wavelength band.

4. The display device of claim 1, wherein the display panel is configured to emit blue light through the first light-emitting region and to absorb light of another color.

5. The display device of claim 1, wherein the colorant comprises a compound represented by Chemical Formula 1:

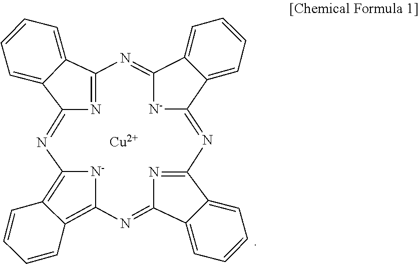

6. The display device of claim 1, wherein the first adjustment portion comprises a liquid crystal, and
wherein the second adjustment portion comprises the liquid crystal and a dichroic dye.

7. The display device of claim 6, wherein the liquid crystal comprises a lyotropic liquid crystal or a host-guest liquid crystal.

8. The display device of claim 6, wherein the liquid crystal comprises a lyotropic liquid crystal and the lyotropic liquid crystal comprises a compound represented by any one of Chemical Formulas 2, 3, 4, or 5:

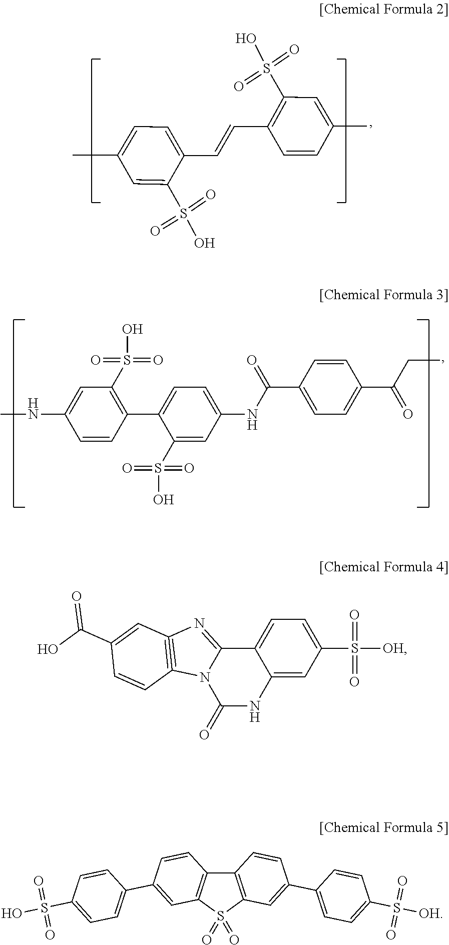

9. The display device of claim 7, wherein the host-guest liquid crystal comprises a compound represented by any one of Chemical Formulas 6, 7, or 8:

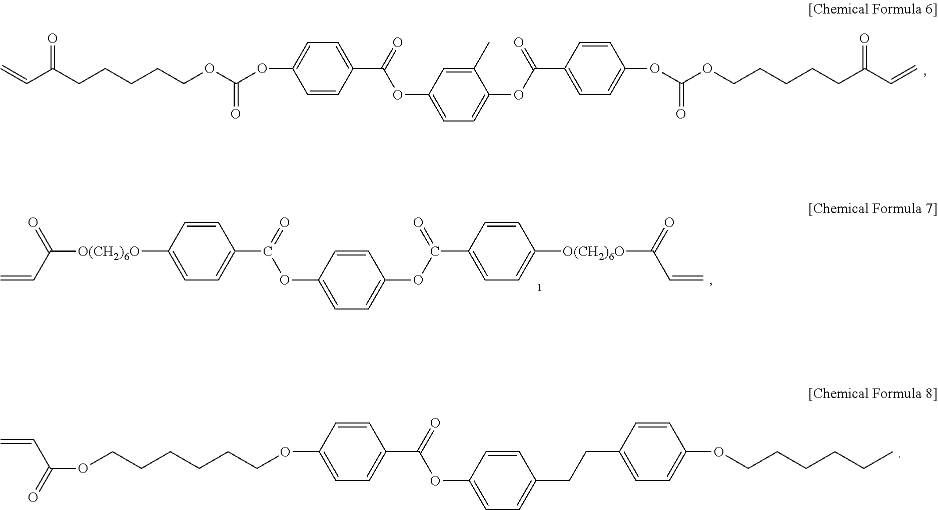

10. The display device of claim 6, wherein the dichroic dye comprises a compound represented by any one of Chemical Formulas 9, 10, 11, 12, or 13:

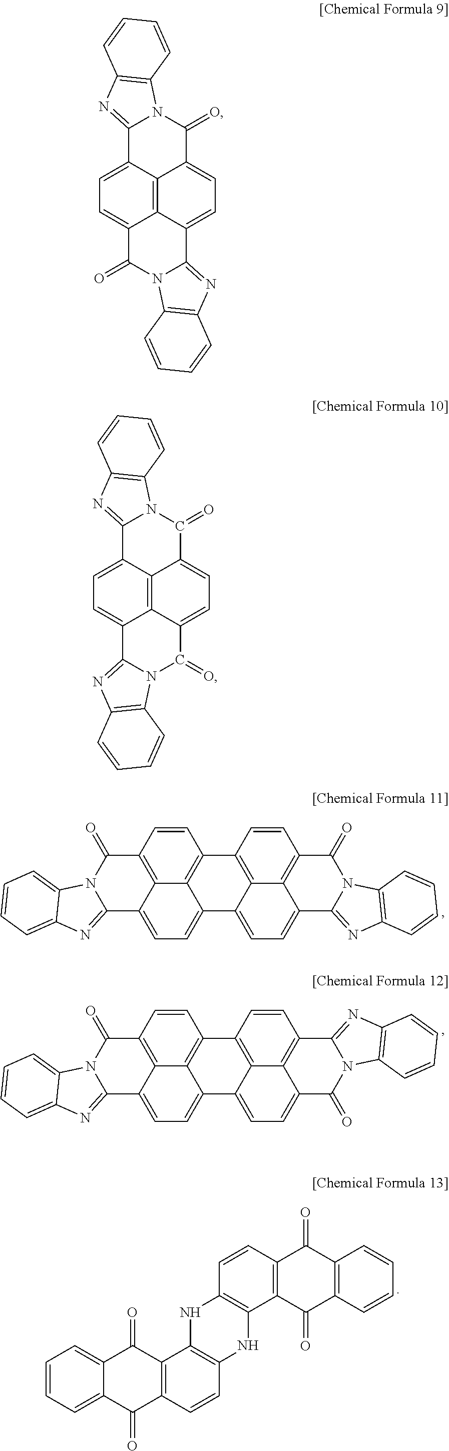 [SMILES: O=c1c2ccc3c4c(ccc(c24)c2nc4ccccc4n12)c(=O)n1c2ccccc2nc31 ; O=c1c2ccc3c(=O)n4c5ccccc5nc4c4ccc(c2c34)c2nc3ccccc3n12 ; O=c1c2ccc3c4ccc5c(=O)n6c7ccccc7nc6c6ccc(c7ccc(c2c37)c2nc3ccccc3n12)c4c56 ; O=c1c2ccc3c4ccc5c6c(ccc(c7ccc(c2c37)c2nc3ccccc3n12)c46)c(=O)n1c2ccccc2nc51 ; O=c1c2ccccc2c(=O)c2c1ccc1[nH]c3c(ccc4c(=O)c5ccccc5c(=O)c43)[nH]c12]

11. The display device of claim 6, wherein the dichroic dye comprises a compound represented by any one of Chemical Formulas 14, 15, 16, or 17:

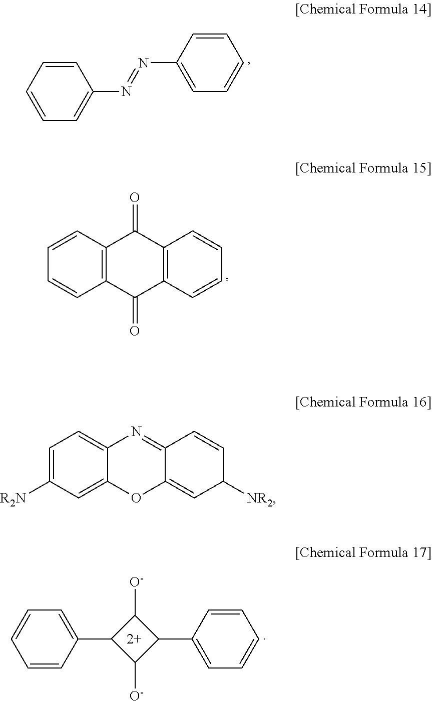

12. The display device of claim 1, wherein a width of the first adjustment portion is greater than a width of the first light-emitting region.

13. A method of manufacturing a display device, the method comprising:
preparing a display panel by forming a pixel defining layer, a plurality of light-emitting layers, a plurality of pixel electrodes, and an encapsulation layer on a substrate;
forming a touch sensing layer on the display panel, the touch sensing layer comprising a touch insulation layer overlapping with a first light-emitting layer of the plurality of light-emitting layers and being configured to selectively transmit light with a wavelength band overlapping with a wavelength band of light emitted from the first light-emitting layer; and
forming a reflection adjustment layer on the touch sensing layer,
wherein the forming of the reflection adjustment layer comprises:
providing a liquid crystal compound on the touch sensing layer; and
dyeing the liquid crystal compound to form a dyed pattern overlapping with a second light-emitting layer of the plurality of light-emitting layers and surrounding at least a portion of the first light-emitting layer.

14. The method of claim 13, wherein providing the liquid crystal compound comprises providing a lyotropic liquid crystal or a host-guest liquid crystal.

15. The method of claim 13, wherein providing the liquid crystal compound comprises coating a lyotropic liquid crystal that is self-aligned.

16. The method of claim 13, wherein providing the liquid crystal compound comprises:
coating a host-guest liquid crystal; and
aligning the host-guest liquid crystal.

17. The method of claim 13, wherein dyeing comprises:
forming a photoresist on the liquid crystal compound;
exposing and developing the photoresist to form a dyeing pattern such that a portion of the liquid crystal compound is exposed;
dyeing a dichroic dye onto the dyeing pattern to form the dyed pattern; and
removing the photoresist.

18. An electronic device comprising:
a display device, comprising:
a display panel in which a plurality of light-emitting regions configured for displaying images are defined;
a touch sensing layer disposed on the display panel; and
a reflection adjustment layer disposed on the touch sensing layer,
wherein the touch sensing layer comprises a touch insulation layer,
wherein, on a plane, the touch insulation layer covers a first light-emitting region of the plurality of light-emitting regions and exposes a second light-emitting region of the plurality of light-emitting regions,
wherein the touch insulation layer includes a colorant,
wherein the reflection adjustment layer comprises a first adjustment portion and a second adjustment portion, the first adjustment portion covering the first light-emitting region and the second adjustment portion covering the second light-emitting region, and
wherein the first adjustment portion is non-polarized, and the second adjustment portion is polarized.

19. The electronic device of claim 18, wherein the first adjustment portion and the second adjustment portion have an integrated shape.

20. The electronic device of claim 19, wherein the display panel is configured to emit light of a first wavelength band through the first light-emitting region,
wherein the touch sensing layer comprises a first electrode, a second electrode, and the touch insulation layer is disposed between the first electrode and the second electrode, and
wherein the touch insulation layer is configured to selectively transmit light of the first wavelength band.
